(19) United States
(12) Patent Application Publication
(10) Pub. No.: US 2026/0188978 A1
(43) Pub. Date: Jul. 2, 2026

(54) SUSPENDED ACTIVE PHOTONIC DEVICES

(71) Applicant: SIVERS PHOTONICS LIMITED, Blantyre Glasgow (GB)

(72) Inventor: Andrew MCKEE, Blantyre Glasgow (GB)

(73) Assignee: SIVERS PHOTONICS LIMITED, Blantyre Glasgow (GB)

(21) Appl. No.: 19/130,808

(22) PCT Filed: Nov. 15, 2023
(86) PCT No.: PCT/GB2023/052997

§ 371 Date: May 16, 2025

(30) Foreign Application Priority Data
Nov. 17, 2022 (GB) 2217254.8

(51) Int. Cl. H01S 5/20; H01S 5/06; H01S 5/12; H01S 5/323

(52) U.S. Cl. CPC H01S 5/2009; H01S 5/0612; H01S 5/12; H01S 5/32391

(57) ABSTRACT

An active photonic device, such as a laser, has an epitaxial layer structure epitaxially grown on a substrate and has an elongate suspended beam supported over an etched void between the suspended beam and the substrate. The etched void extends fully under the suspended beam's width. The suspended beam has an active region for providing optical gain, an elongate waveguide configured to guide optical radiation along the suspended beam's length and a doped layer for conveying current in a circuit supplying power to the active region. Electrodes arranged with the doped layer to direct current in the circuit vertically through the active region above the etched void.

The present invention relates to active photonic devices, chips and photonic chip assemblies. In particular, it relates to suspended active photonic devices, such as suspended Distributed Feedback (DFB) lasers useful in self-heating laser applications.

### BACKGROUND ART

In the field of active photonic devices, devices such as compound semiconductor lasers may be used for sensing gases.

EP1493017B1 discloses a method for sensing gases using a semiconductor diode laser spectrometer by applying a step function electrical pulse to a semiconductor diode laser to cause the laser to output a continuous wavelength chirp for injecting into an optical cell, and using the wavelength variation provided by the wavelength chirp as a wavelength scan. The chirp arises from heating effects induced by the electrical pulse.

However, such lasers that operate in mid-infrared, where the chemical fingerprints of most chemical compounds lie, are inherently electro-optically inefficient.

In the field of active photonic devices, devices such as compound semiconductor lasers may be fabricated suspended in membranes to achieve better optical confinement by introducing a void beneath the laser's optical cavity.

US2019207370A1 discloses a lateral current injection laser, where an opening is defined by a wet etch, then a “smart cut” process is used to enclose the opening before semiconductor regrowth including growth of the active layers.

US2019207370A1 discloses that such confinement of the optical mode enables enhanced heat dissipation to the substrate.

Laser self-heating is known to limit the output power and efficiency of a laser during operation. In a membrane laser, heat cannot flow down to the substrate because the void beneath the laser optical cavity is thermally insulating. To avoid self-heating effects, known membrane lasers are supported from the sides of the waveguide defining the laser's optical cavity, with support along the length of the waveguide. Thus known membrane lasers are designed to achieve good heat flow from the membrane.

In DFB semiconductor lasers, self-heating when modulating the current, such as switching the laser on, is known to lead to laser output wavelength chirp. As such chirp is unwanted, designs for DFB lasers are directed to reducing self-heating and therefore chirp.

However, for a device whose operation depends on a wavelength chirp, the self-heating effect is desirable, and high thermal conductivity to take heat away from an active region becomes a problem.

Furthermore, suspended lasers may be fabricated with the void being formed by a preferential wet etch which undercuts the laser. It is a problem that the undercutting also affects the outer sides of the void, causing the design to use more real-estate and to be less mechanically strong.

### SUMMARY OF INVENTION

It is desirable to provide active photonic devices, chips and photonic chip assemblies that overcome at least some of the above-identified problems. In particular, it is desirable to provide active photonic devices that are heated by self-heating, with no additional heater and heating circuit required, in which there is good thermal isolation of the active photonic device, and the thermal mass of the active photonic device is minimised, while being well thermally isolated, without compromising mechanical strength or efficient use of chip real-estate.

According to a first aspect of the present invention, there is provided an active photonic device comprising:
a substrate;
an epitaxial layer structure epitaxially grown on the substrate and comprising an active region for providing optical gain to radiation and comprising a doped layer for conveying current in a circuit supplying power to the active region;
an elongate suspended beam supported over an etched void between the suspended beam and the substrate, the etched void extending fully under the suspended beam's width, the suspended beam comprising:
   the active region;
   an elongate waveguide configured to guide the radiation along the suspended beam's length; and
   the doped layer; and
electrodes arranged with the doped layer to direct current in the circuit vertically through the active region above the etched void.

Preferably, the electrodes are arranged with the doped layer to direct current in the circuit lengthwise in the suspended beam.

Preferably, the elongate waveguide is configured to guide the radiation in a propagation direction, and the suspended beam further comprises a grating at least partially periodic along the propagation direction.

Preferably, the suspended beam further comprises a grating at least partially periodic along the suspended beam's length.

Preferably, the suspended beam is supported at an end of the waveguide over the void.

Preferably, the active photonic device further comprises a flange at an end of the waveguide, the flange supporting the suspended beam, wherein the flange comprises a facet.

Preferably, the flange comprises an etched facet.

Preferably, the suspended beam is supported over the void only at an end or at both ends of the waveguide.

Preferably, the suspended beam is cantilevered over the void.

Preferably, the suspended beam is supported over the void from underneath.

Preferably, the void comprises air.

Preferably, the suspended beam has an etch stop layer below the active region as its lower layer.

Preferably, the suspended beam has a protective coating on its sidewalls.

Preferably, the active photonic device further comprises opposing sidewalls facing the suspended beam's sidewalls, wherein the opposing sidewalls have a protective coating.

Preferably, the active photonic device comprises a trough that includes the void, the trough comprising a planar opposing sidewall facing the suspended beam's sidewall, wherein the planar opposing sidewall has its plane at a first angle with respect to a crystallographic plane of the substrate such that in use with a preferential wet void etch a first wet etch front is pinned to the base of the planar opposing sidewall.

Preferably, the suspended beam has a planar sidewall with its plane at a second angle, different from the first angle, with respect to the crystallographic plane of the substrate such that in use with the preferential wet void etch a second etch front of the preferential wet void etch is unpinned from the base of the suspended beam's sidewall, thereby allowing more undercutting of the suspended beam's lower surface compared to undercutting of the planar opposing sidewall by the preferential wet void etch.

Preferably, the active photonic device further comprises a heater operable to heat the waveguide.

According to a second aspect of the present invention, there is provided a photonic chip comprising the active photonic device of the first aspect.

According to a third aspect of the present invention, there is provided photonic chip assembly comprising the photonic chip of the second aspect and a photonic integrated circuit having a coupled waveguide aligned to be optically coupled to the waveguide of the suspended beam.

According to a fourth aspect of the present invention, there is provided a method of fabrication of a suspended active photonic device, the method comprising the steps:
providing a layer structure epitaxially grown on a substrate and comprising an active region for providing optical gain to radiation and comprising a doped layer for conveying current in a circuit supplying power to the active region;
fabricating in the epitaxial layer structure an elongate waveguide configured to guide the radiation;
fabricating an elongate suspended beam supported over an etched void between the suspended beam and the substrate, the etched void extending fully under the suspended beam's width, the suspended beam comprising the active region, the doped layer and the elongate waveguide, with the elongate waveguide configured to guide the radiation along the suspended beam's length; and
before etching the void, fabricating electrodes arranged with the doped layer to direct current in the circuit vertically through the active region above the etched void.

Preferably the method further comprises fabricating the electrodes arranged with the doped layer to direct current in the circuit lengthwise in the suspended beam.

### BRIEF DESCRIPTION OF DRAWINGS

Embodiments of the present invention will now be described, by way of example only, with reference to the drawings, in which:

FIGS. 1a to 1c illustrate, in schematic form, a known etched-facet distributed feedback (DFB) laser chip, in orthographic and cross-section views.

FIGS. 2a to 2d illustrate, in schematic form, steps of fabrication of a suspended ridge laser in accordance with an embodiment of the present invention, before the etching of the void.

FIGS. 3a to 3c illustrate, in schematic form, a suspended ridge laser in accordance with an embodiment of the present invention, in plan, cross-section and orthographic views.

FIGS. 4a to 4c illustrate, in schematic form, a suspended ridge laser in accordance with another embodiment of the present invention, in plan, cross-section and orthographic views.

FIGS. 5a to 5c illustrate, in schematic form, a suspended buried heterostructure laser in accordance with another embodiment of the present invention, in plan, cross-section and orthographic views.

FIG. 6 illustrates, in schematic form, a cantilevered suspended ridge laser, supported at one end, in accordance with another embodiment of the present invention, in an orthographic view.

FIG. 7 illustrates, in schematic form, a suspended ridge laser supported by a pillar in accordance with another embodiment of the present invention, in an orthographic view.

FIG. 8 illustrates, in schematic form, a suspended ridge laser supported by a fin in accordance with another embodiment of the present invention, in an orthographic view.

FIG. 9 illustrates, in schematic form, a suspended ridge laser supported by a wall in accordance with another embodiment of the present invention, in an orthographic view.

FIG. 10 illustrates, in schematic form, a photonic chip assembly in accordance with an embodiment of the present invention.

### DETAILED DESCRIPTION

In this description and claims, optical gain and radiation relate to electromagnetic radiation over a range of wavelengths not limited to visible radiation, such as wavelengths spanning ultraviolet, visible and infrared radiation. An InP distributed feedback (DFB) laser is described as an example of an active photonic device. Other compound semiconductor based devices may be used with embodiments. For example photonic devices based on GaAs, GaSb, or GaN, or photonic devices based on other material systems such as Si, may be used. Rather than the DFB laser example described herein, other active photonic devices may be used, such as Fabry Perot lasers, modulators, semiconductor optical amplifiers (SOAs), reflective semiconductor optical amplifiers (RSOAs) used stand-alone or in external cavity lasers.

The examples described herein relate to active photonic devices fabricated with a ridge or buried waveguide with an etched facet, but the skilled person will appreciate that embodiments may include photonic devices fabricated with one or more cleaved facet.

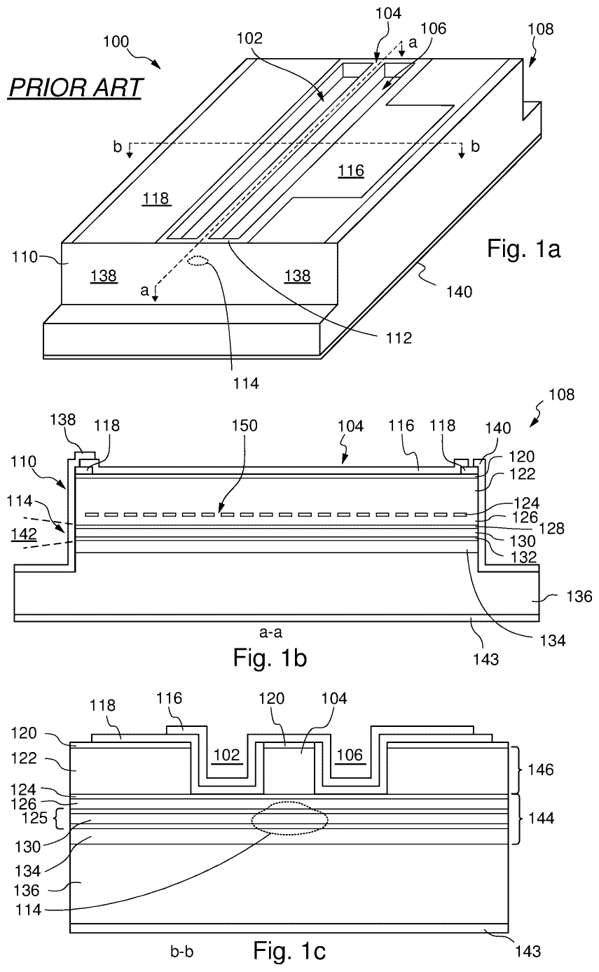

FIG. 1 illustrates a known active photonic device, in this example an etched-facet DFB laser chip 100, with a compound semiconductor laser on an InP (indium phosphide) substrate. FIG. 1a is an orthographic view of the laser chip 100. FIG. 1b is a cross-section (not to scale) along a-a shown in FIG. 1a. FIG. 1b is thus a lengthwise cross-section through the waveguide 104 along its propagation direction (length). FIG. 1c is a cross-section (not to scale) along b-b shown in FIG. 1a. FIG. 1c is thus a cross-section across the waveguide 104 perpendicular to its propagation direction.

The structure of the laser chip 100 is now described in the context of its wafer-scale fabrication.

A ridge waveguide 104 is defined by a waveguide etch. A pattern of openings in a hard mask in a lithographic step defines trenches 102, 106 that are etched to define the ridge waveguide 104 in between them. An insulating dielectric material 118 covers most of the top surface, and a contact window is opened up in the dielectric along the top of the ridge 104. Subsequently, metal 116 is deposited covering the ridge waveguide and making contact through the contact window to the top of the ridge waveguide 104.

A pad of the metal 116 at one side of the ridge waveguide is used as an area for soldering or bonding to the metal. In subsequent fabrication steps, a patterned hard mask and facet etch defines front and rear etched facets 110, 108 at either end of the ridge waveguide 104. The facet etch creates an etched surface which extends either side of the etched facet. The facet etch is deeper than the ridge etch.

A small horizontal spacing is provided between the ridge trenches 102, 106 and the facet etch features, so that the front and rear etched facets 110, 108 are etched as flat planes rather than having corners with the ridge waveguide, which would etch unevenly and would be detrimental to the smoothness of the facet at the end of the waveguide. This results in a structure shaped like a T, with the waveguide being the trunk of the T, and walls 112 being the crossbar of the T in the form of a flange. The effect of the spacing and resulting flanged T-shaped structure is to ensure that the facet is smooth to provide efficient and reproducible transmission through optical coupling regions, or internal reflection at, the facets.

After the facet etch, an anti-reflective (AR) coating 138 is applied to one etched facet 110 and a high-reflectance (HR) coating 140 (or an AR coating, not shown) is applied to the other etched facet 108 at the other end of the waveguide 104. Anti-reflective coatings may be applied to just one facet for a laser, or one or both facets for Semiconductor Optical Amplifiers (SOAs) or Electro-Absorption Modulators (EAMs).

Finally, a metallisation step coats the underside of the wafer with metal 143.

With reference to FIGS. 1a and 1b, in operation the laser cavity, comprising the waveguide 104 bounded by facets 108 and 110 at either end, outputs optical radiation 142 through an optical coupling region 114.

With reference to FIGS. 1b and 1c, the layer structure will now be described in detail. From the top in FIG. 1b, a p-metal layer 116 extends down through a window in the dielectric layer 118. The p-metal layer 116 makes contact to a p-type InGaAs contact layer 120, which is the top epitaxially-grown layer. Below that, a p-type InP cladding layer 122 is followed by a p-type etch stop/grating layer 124. The etch that stops on that layer 124 is the waveguide ridge etch, as illustrated in FIG. 1c. Next, a p-type InP spacer layer 126 is followed by a p-type separate confinement heterostructure (SCH) layer 128, an undoped multi-quantum well (MQW) layer 130, and an n-type SCH layer 132. The SCH and MQW layers are the optically active layers in the laser.

The n-type InP buffer layer 134 is the first of the epitaxial layers that is grown on the n-type InP substrate 136.

In a distributed feedback (DFB) laser, a grating is superimposed on the waveguide to provide optical feedback in the laser cavity. In this example, the grating is made by performing the epilayer growth in two stages and in between the stages patterning the grating. First, a lower epitaxial layer structure 144 is grown on the substrate, starting with the n-type InP buffer layer 134 then the SCH and MQW active layers 125 then the p-type InP spacer layer 126 and the etch stop/grating layer structure 124. Electron beam lithography is used to define a grating pattern 150 (shown in FIG. 1b), which is transferred by etching into the etch stop/grating layer structure 124.

After the grating patterning, the upper epitaxial layer structure 146 is overgrown on the lower epitaxial layer structure 144, using for example metalorganic vapour-phase epitaxy (MOVPE/MOCVD). The upper epitaxial layer structure 146 includes the p-type InP cladding layer 122 under the p-type InGaAs contact layer 120.

This specific layer structure is suitable for a laser as well as an SOA. However, the layer structure may be optimised for different active photonic devices. In this laser example, the front and rear etched facets 110, 108 are coated with a PECVD-deposited silicon nitride AR coating 138 and an HR coating 140 respectively. The AR coating is selectively removed after deposition to allow bonding to metallic layers. Finally, the n-metal layer 143 is shown.

In operation, as shown at the left of FIG. 1b, a beam of optical radiation 142, illustrated bounded with dashed lines, is output from the etched facet 110 at the optical coupling region 114. In this example, the optical radiation is output from the optically active layers of the ridge waveguide 128, 130, 132 (collectively labelled 125 in FIG. 1c) into the air to the left of the front etched facet 110. For an SOA example (not shown), instead of an HR coating 140 another AR coating is applied to the rear etched facet 108 and radiation is input to the waveguide at the rear etched facet 108. With reference to FIG. 1c, the p-metal layer 116 can be seen on top of the dielectric layer 118 as it covers trenches 102, 106 either side of the ridge waveguide 104. The p-metal layer 116 contacts the top of the ridge 104 through a window in the dielectric 118. The trenches 102, 106 are etched by the waveguide ridge etch, which selectively stops on the p-type etch stop/grating layer 124.

The location of the optical coupling region 114 is shown projected along the waveguide from the etched facet 110 onto this cross-section plane b-b. It is centred horizontally with respect to the ridge waveguide 104 and centred vertically with respect to the undoped MQW layer 130. The optical mode roughly corresponds to the projected coupling region 114.

A contact is made by the metal layer 116 at the top of ridge 104 to the p-type InGaAs contact layer 120.

In the drawings, features labelled with the same numerals correspond to the same features in subsequent drawings. Therefore a description of a feature in any drawing should also apply to a feature labelled with the same numeral elsewhere in this description.

Embodiments provide a suspended DFB laser in which the grating and laser gain region are in a longitudinally-supported beam suspended in a trough, and the suspended area is limited to the laser, with thermally isolated support at the ends. Optionally, the beam is angled so it is undercut by a preferential wet etch to form a void under the beam, while the outer sides of the trough are not, or are much less, undercut. Typically, the void comprises air, but alternatively, it may comprise other substances more thermally insulating than the substrate, such as a gas, liquid, solid or foam, or even a partial vacuum.

In a self-heating DFB laser, the active region generates heat, and the heat affects the effective index of the waveguide, which modulates the Bragg lasing wavelength of light generated by the active region in the cavity, under the influence of the DFB grating.

A problem that embodiments solve is that thermal conductivity that takes heat away from the active region is undesirable in a self-heating laser.

In embodiments, because the grating and laser gain region are on a longitudinally-supported suspended beam, it mechanically reduces the path for heat flow from the laser. The laser can be only supported at the ends/facets, rather than the more thermally conductive sides of a membrane. The metal to semiconductor contacts may be on the beam and the interconnects may run the length of the beam. Because electrical current is supplied to the gain region from end supports, rather than sides, it also allows for better thermal isolation.

This improved thermal isolation has the advantage that the waveguide at the grating is heated by the self-heating of the laser and no additional heater and heating circuit are required.

In embodiments, the beam is supported by piers in the form of flanges comprising the laser's etched facets.

Advantages of this approach are that the thermal mass of the beam is minimised, while being well thermally isolated, without compromising mechanical strength of the beam support. Furthermore, the radiation output location of the device is mechanically fixed to the substrate The outer sides of the trough are hardly undercut, because of the differently angled opposing trench sidewalls. For certain InP-layer sidewalls, including the outer sides of the trough, the etch is “pinned” by the epitaxial structure at the mask and is constrained, for example to form an etched wall of 88 degrees. Because the outer sides of the trough are not significantly undercut, the lateral etching is self-limiting, so variation in etch rate only affects depth variation of the trough and void. Furthermore, it provides improved mechanical integrity. So, the areas of the device either side of the trough can be used for placement of bond pads for bonding.

In contrast, for the angled sidewall at the edge of the suspended beam, the etch front becomes unpinned and the etch front progresses sideways with a steeper angle than 88 degrees, as well as progressing downwards. This rapidly undercuts the whole width of the suspended beam.

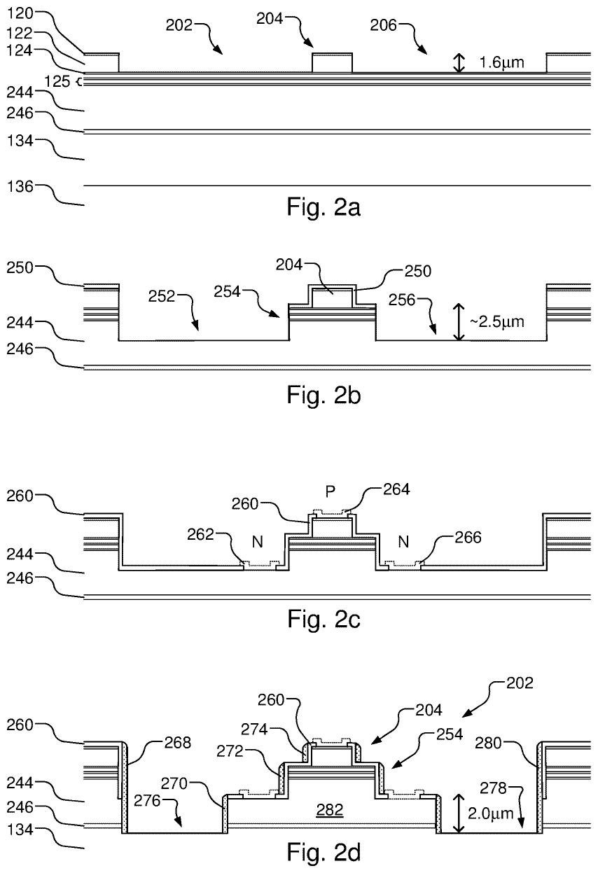

FIGS. 2a to 2d illustrate, in schematic form, cross-sections of steps of fabrication of a suspended DFB ridge laser in accordance with an embodiment of the present invention, before the etching of the void.

A substrate 136 is provided with an epitaxial layer structure comprising an active region 125 for providing optical gain to radiation and comprising a doped layer 122 for conveying current in a circuit supplying power to the active region 125. Thus the active region 125 is epitaxially grown on the substrate. As described with reference to FIGS. 1a to 1c, in between lower and upper epitaxial structure growth stages, electron beam lithography is used to define a grating pattern 150 (shown in FIG. 1b), which is transferred by etching into the etch stop/grating layer structure 124.

With reference to FIG. 2a, an elongate waveguide 204 is fabricated. A hard mask (not shown, for example comprising silicon dioxide) is lithographically patterned to transfer the pattern of trenches 202, 206 etched into the p-type InP cladding layer 122. An etch (in this example 1.6 μm deep) is masked by the hard mask and selectively stops on the p-type etch stop/grating layer 124. This leaves the ridge 204.

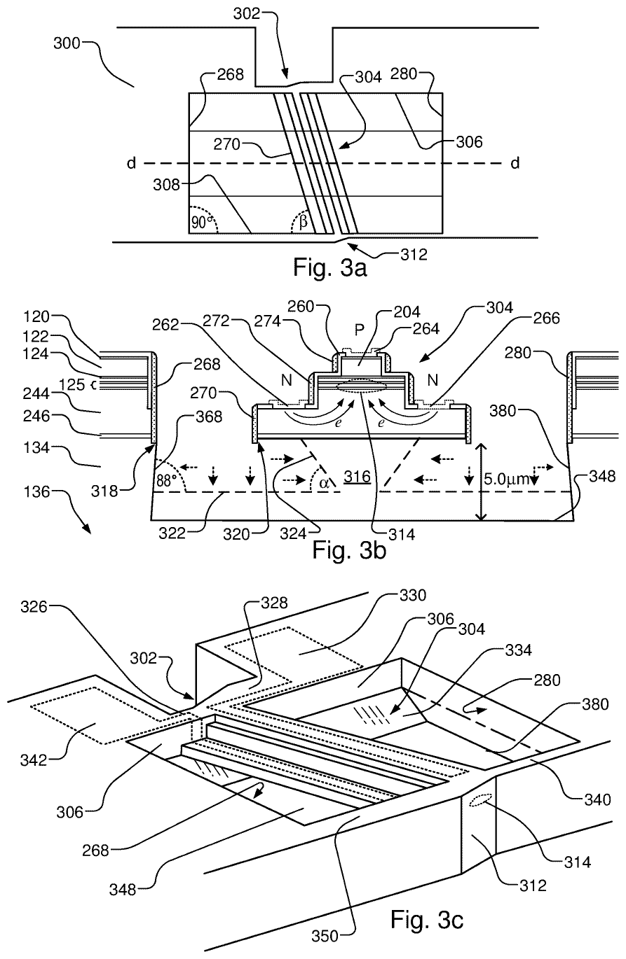

In FIG. 2a, the thickness of the n-type InP buffer layer 134 is not drawn to the same scale as in FIGS. 3b, 4b and 5b. It is drawn thinner in FIG. 2a, to allow the substrate layer 136 to be shown. In those other figures, the substrate 136 is not shown, its position is instead indicated by a downward pointing arrow.

With reference to FIG. 2b, a dielectric hard mask 250, for example comprising silicon dioxide, is deposited on the wafer and patterned. An etch (in this example about 2.5 μm deep) is performed into the n-type InP spacer/contact layer 244, masked by the dielectric hard mask 250, to define n-contact shelves 252, 256. This leaves the ridge 204 on shoulders 254.

With reference to FIG. 2c, a dielectric layer 260, for example comprising silicon dioxide, is deposited on the wafer and contact windows are lithographically defined, then p-contacts 264 and n-contacts 262, 266 are made by lithographically patterning contact metal (for example using a lift off process) to cover the contact windows so as to make electrical contact to the p-type InGaAs contact layer 120 and n-type InP spacer/contact layer 244 respectively. As illustrated in FIGS. 3c, 4c and 5c the contact metal is patterned with and/or connected to other metal tracks and pads to form electrodes arranged with the doped p-type InGaAs contact layer 120 to direct current in the circuit lengthwise in the suspended beam to and from the active region 125 and vertically through the active region 125.

With reference to FIG. 2d, the first step of fabricating a suspended beam supported over a void is shown. A trough hard mask layer (not shown, for example comprising silicon dioxide) is deposited on the wafer and lithographically patterned with trough pattern. An etch (in this example 2.0 μm deep) is performed further into the n-type InP spacer/contact layer 244, masked by the trough hard mask layer. The etch punches through a quaternary InGaAsP etch stop layer 246 and extends a short distance down into the n-type InP buffer layer 134. This defines trenches 276, 278 into which the wet void etch will proceed. This leaves the ridge 204 and shoulders 254 on the body 282 of the beam which will subsequently be undercut and suspended.

A spacer dielectric layer is deposited on the wafer and, without lithographic patterning, a blanket etch is performed. This leaves sidewall spacers 268, 270, 272, 274, 280 (because the structure is symmetrical, not all sidewall spacers are numerically labelled in the Figures). These sidewall spacers protect the InP layers from the wet void etch.

The last step of fabricating the suspended beam is described below with reference to FIG. 3c.

FIGS. 3a to 3c illustrate, in schematic form, a suspended DFB ridge laser in accordance with an embodiment of the present invention, in plan, cross-section and orthographic views.

With reference to FIG. 3a, a plan view of an active photonic device 300, in this example a suspended DFB ridge laser device, is shown. The laser has a suspended beam 304, comprising an elongate waveguide. Etched facets 302, 312 form an optical cavity with the waveguide. The suspended beam 304 spans a trough bounded by walls 268, 306, 280, 308.

The suspended beam 304 has a sidewall 270. A planar opposing sidewall 268 faces the suspended beam's sidewall 270. The planar opposing sidewall has its plane at a first angle (in this example 0°) with respect to a crystallographic plane of the substrate (and by extension to a crystallographic plane of the epilayers grown epitaxially on the substrate). The suspended beam 304 has a planar sidewall 270 with its plane at a second angle (in this example 90°−β), different from the first angle, with respect to the crystallographic plane of the substrate.

With reference to FIGS. 3b and 3c, the suspended DFB ridge laser device 300 shown in FIG. 3a is shown in cross-section (along line d-d in FIG. 3a) and orthographic views respectively. The device has a substrate 136, and an elongate suspended beam 304 supported over an etched void 316 between the suspended beam 304 and the substrate 136. The etched void 316 extends fully under the suspended beam's width. The suspended beam has an active region 125 for providing optical gain to radiation, a doped layer 122 for conveying current in a circuit supplying power to the active region 125, and an elongate waveguide configured to guide the radiation along the beam's length. The optical mode of radiation optically confined and guided by the waveguide roughly corresponds to the coupling region 314 projected from the end facet onto the section in FIG. 3b. Electrodes are arranged with the p-type InGaAs contact doped layer 120 to direct current in a direction along the suspended beam's 270 length to the active region. The typically metal electrodes form an ohmic contact to the doped layer. In this example, the electrodes comprise the p-contact bond pad 330 connected by a track crossing the end of the suspended beam 304 and through contact windows 264 to meet the doped layer, to direct the current to flow along the suspended beam's 304 length to the active region. The electrodes also comprise the n-contact bond pad 342 connected by a track crossing the end of the suspended beam 304 and through contact windows 262 266 to connect via the layer 244 to the active region 125. The flow of electrons “e” in the n-type layer 244 is indicated by curved arrows. The current flows in the opposite direction to the electrons.

In FIG. 3, the n-contact windows 262, 266 are shown on both sides of the suspended beam. However, for simplicity only the left-hand contact window 262 is shown with its bond pad 342 in FIG. 3c. The skilled person will appreciate that one or more tracks may enter the beam from one or both ends for either or both p and n contacts, to direct the current in the circuit lengthwise along the suspended beam.

In other examples (not shown) the bond pad and metallisation may stop short of the end of the suspended beam, not reaching onto it, but the arrangement of bond pads and doped regions still direct current to flow lengthwise in the suspended beam 304 to and from the active region 125 and vertically through the active region 125. This arrangement may be achieved using insulating regions if the positive and negative electrodes are at the same end of the suspended beam. Alternatively, electrodes that do not reach onto the beam may be placed at opposite ends of the beam, so that current flows along the beam from the positive to the negative electrodes at different ends.

In this example, the current flows down from the p-doped layer above the active region. In other examples (not shown) the current may flow up from a p-doped layer below the active region to an n-doped layer above it.

As described with reference to FIGS. 2a to 2d, the suspended beam further comprises a grating at least partially periodic along the propagation direction. The grating may be entirely periodic or may have different periodic sections phase shifted with respect to each other. This is not shown in the lateral cross-section of FIG. 3b, but the p-type etch stop/grating layer 124 shown in FIG. 3b, if viewed in a longitudinal cross section like FIG. 1b, would appear as a broken line with the period of the grating.

The suspended beam 304 is supported at an end of the waveguide over the void 316. In this example, it is supported at both ends, but in other examples (not shown), it may be supported at just one end, with the beam cantilevered over a void.

In this example the electrodes are arranged with the doped layer to direct current from the end of the waveguide lengthwise along the waveguide to and from the active region. In another embodiment (not shown), the beam may be supported from the centre of the waveguide, with the suspended beam projecting and cantilevered out of both ends of a supporting flange structure, across which electrodes run and supply current, lengthwise along the projecting sections of waveguide, to the active region.

In this example, flanges 326, 328 at one end and flanges 350, 340 at the other end of the waveguide support the suspended beam 304. Each flange comprises a respective etched facet 302, 312.

Support of the suspended beam is configured such that in operation there is greater heat flow from the active region to the substrate lengthwise in the suspended beam than widthwise. Heat generated by the laser is thus hindered from flowing to the substrate via the relatively long sides of the waveguide. The heat has to flow mainly lengthwise along the beam via the relatively narrow support or supports to the substrate. Because there is less heat flow widthwise from the longer sides of the waveguide, there is lower overall heat flow from the active region to the substrate. Therefore there is better thermal isolation of the laser. This results in more heat being retained in the suspended beam, than would be the case for a known side-suspended membrane laser, for example. Therefore, when the laser is turned on the temperature of the suspended beam increases more rapidly, causing an enhanced wavelength chirp, for example being faster and/or larger in magnitude.

In this example, the suspended beam 304 is supported over the void only at ends of the waveguide. In other examples (not shown), the suspended beam may be supported at an end and also away from the ends, for example in the middle. Preferably, the suspended beam is supported over the void more at ends than at sides of the waveguide, which gives better thermal isolation of the laser, which is advantageous for self-heating. For the same reason, the suspended beam is preferably supported over the void more from underneath than from sides of the waveguide.

The suspended beam 304 has a quaternary etch stop layer 246 below the active region as its lower layer. The suspended beam 304 has a protective coating on its sidewalls 270, 272, 274 (not all coatings and sidewalls are numerically labelled because the device is symmetrical). Opposing sidewalls 268, 280 face the suspended beam's sidewalls and have a protective coating.

The protective coatings, formed by the sidewall spacer process described with reference to FIG. 2d, prevent the selective wet void etch from etching the covered InP. Similarly, the selective void etch etches InP 134 in the trough, but does not etch the quaternary etch stop layer 246. As a result of the protective coatings and quaternary etch stop layer 246, the InP body of the suspended beam is left intact after the wet void etch.

As well as being selective, i.e. having different etch rates for different materials, the void etch is preferential, in that its etch rate depends on the orientation of crystal planes of the substrate and epilayers.

As mentioned above, the opposing sidewall 268 facing the suspended beam's sidewall 270 is planar and has its plane at a first angle (in this example 0°) with respect to a crystallographic plane of the substrate. In use with the preferential wet void etch the wet etch front 368 is pinned to the base 318 of the planar opposing sidewall 268. In this example, this results in very little undercutting by the wet void etch at the walls of the trough.

However, the suspended beam 304 has its planar sidewall 270 with its plane at a second angle (in this example 90°−β) different from first angle, with respect to the crystallographic plane. In use with the preferential wet void etch, the wet etch front 324 of the undercut preferential wet void etch is unpinned from the base 320 of the suspended beam's sidewall 270, thereby allowing more undercutting of the suspended beam's lower surface compared to undercutting of the planar opposing sidewall. Dotted arrows indicate the progress of the wet void etch, with larger arrows indicating faster etch rate.

Because the wet void etch is preferential, abutments 334 extend in a slope down from the end walls of the trench 306, 308, to the floor of the trough 348. Thus, the laser is supported by the truncated apex where an end facet and a slope meet. The flanges are thus each reinforced by the preferentially-etched sloped abutment 334 under the beam. This adds to the mechanical support of the suspended beam.

In another example (not shown) the device further comprises a heater operable to heat the waveguide. The heater may be for example a platinum strip deposited on an insulating dielectric layer on the top or shoulder or body of the beam 134.

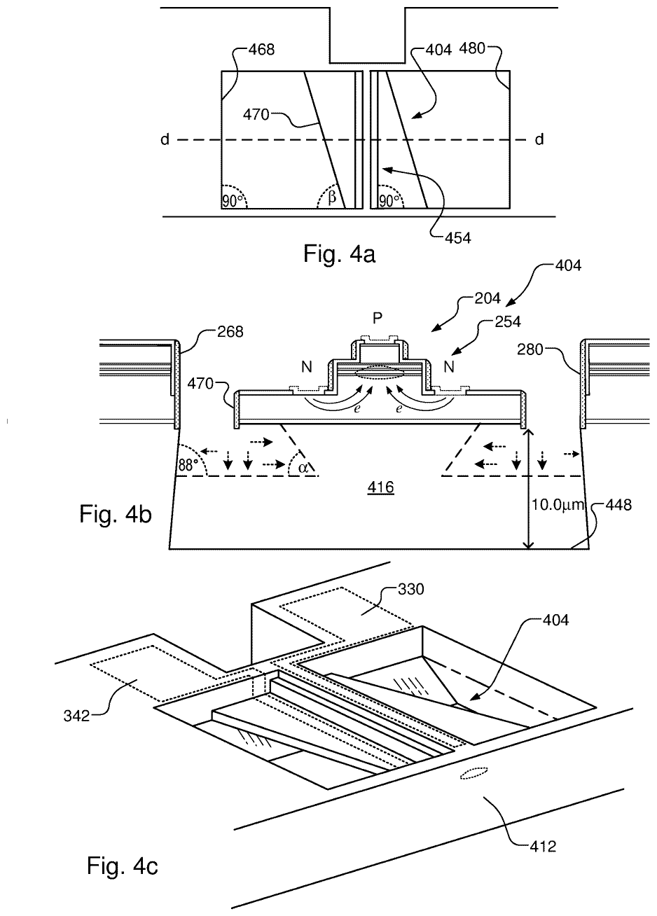

FIGS. 4a to 4c illustrate, in schematic form, a suspended DFB ridge laser in accordance with another embodiment of the present invention, in plan, cross-section and orthographic views.

The embodiment illustrated in FIGS. 4a to 4c is similar to that described with reference to FIGS. 2a to 3c, except that the waveguide 454 defined by the shoulder 254 and ridge 204 are at a different angle from the sidewalls 470 of the body the suspended beam 404. In the example of FIGS. 4a to 4c, the shoulder 254, ridge 204 and thus waveguide 454 are parallel to the opposing sidewalls 468, 480 of the trough. To accommodate the waveguide (shoulders and ridge) 454 on the body of the suspended beam, the body of the suspended beam 404 has to be wider, as compared to that shown in FIGS. 3a to 3c. Therefore, the wet void etch takes longer to undercut the suspended beam. This means that the floor 448 of the trough and void 416 are etched deeper (10 μm in this example) by the longer wet void etch. In this example, the end facet 412 is not angled with respect to the substrate.

This embodiment has the advantages that the waveguide orientation is not constrained by being aligned to the crystallographic planes needed for undercut etching. Also, the suspended beam is more rigidly supported as it has longer edges in connection with the flanges. However, the larger suspended beam has a larger thermal mass, which can be less advantageous for rapid self-heating applications.

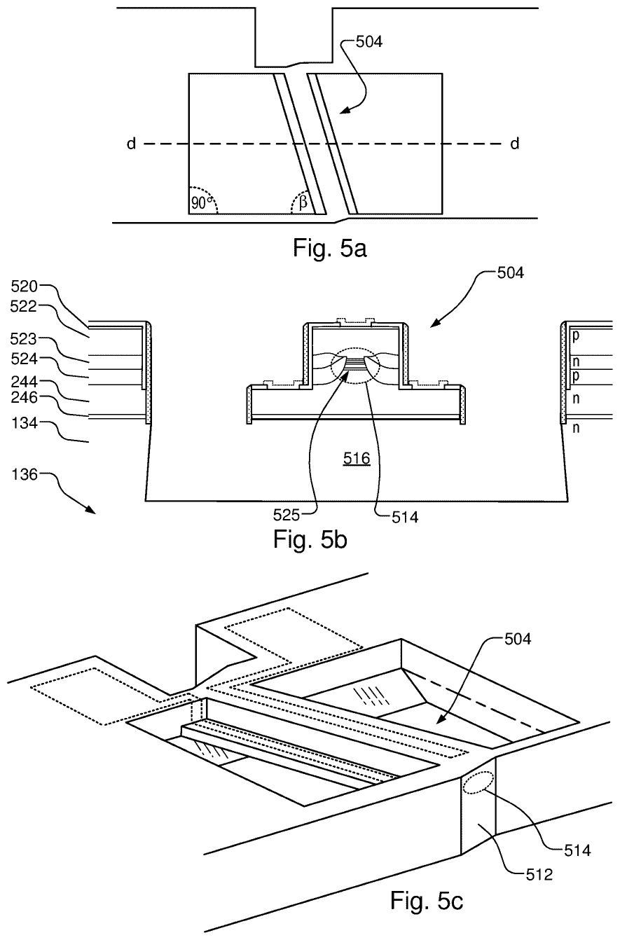

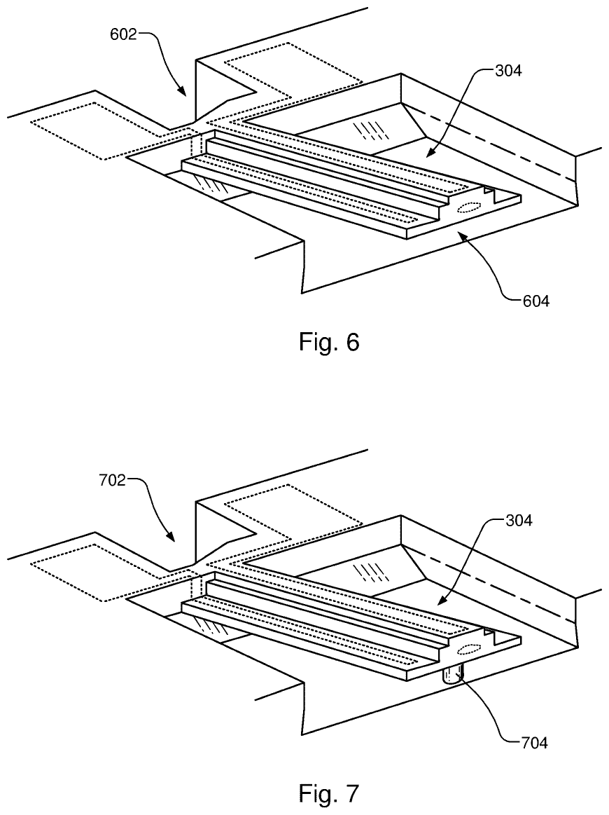

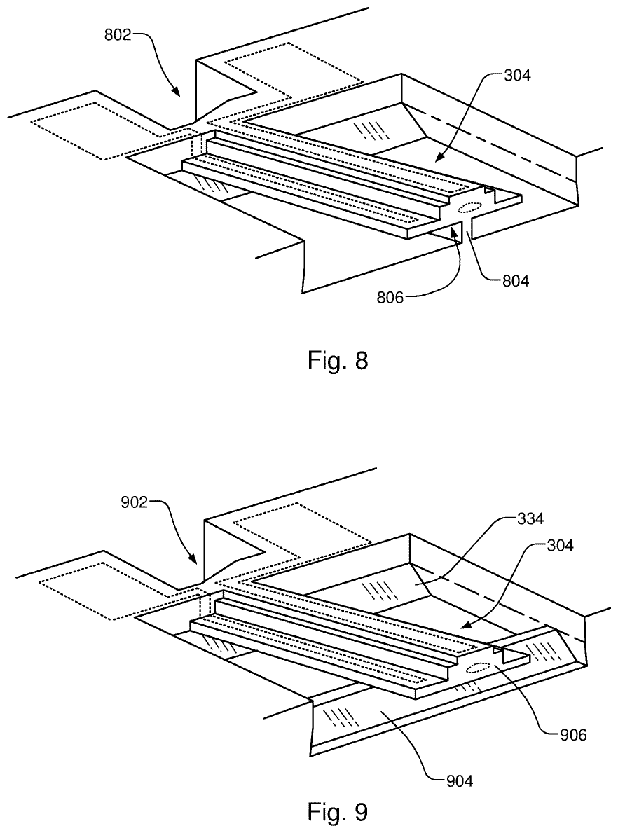

FIGS. 5a to 5c illustrate, in schematic form, a suspended DFB buried heterostructure laser in accordance with another embodiment of the present invention, in plan, cross-section and orthographic views.

The embodiment illustrated in FIGS. 5a to 5c is like that described with reference to FIGS. 2a to 3c, except that instead of a ridge waveguide, a buried heterostructure waveguide is used.

A substrate 136 is provided with a layer structure comprising an active region 525 for providing optical gain to radiation and comprising a doped layer 522 for conveying current in a circuit supplying power to the active region 525. As described with reference to FIGS. 1a to 1c, in between epitaxial structure growth stages, electron beam lithography is used to define a grating pattern (like the grating 150 shown in FIG. 1b), which is transferred by etching into the etch stop/grating layer above the active region 525.

With reference to FIGS. 5a and 5b, the suspended beam 504 has no ridge. With a buried heterostructure process, the active region 525 remains in an etched mesa. The active region and layers immediately above and below are nearly the same layers as described with reference to FIGS. 1b and 1c, i.e. going downwards from the p-type contact layer 520, a p-type InP cladding layer 522 (thicker than the corresponding cladding layer 122 of FIG. 1b) is followed by a p-type etch stop/grating layer. Next, a p-type InP spacer layer is followed by a p-type separate confinement heterostructure (SCH) layer, an undoped multi-quantum well (MQW) layer, and an n-type SCH layer. The SCH and MQW layers are the optically active layers in the laser.

Below the active layers, the n-type InP spacer/contact layer 244, the quaternary etch stop layer 246, the n-type InP buffer layer 134 and substrate 136 are the same as described with reference to FIG. 3b.

A buried heterostructure waveguide has a larger optical mode than a ridge waveguide with similar layer thicknesses. The location of the optical coupling region 514 is shown projected along the waveguide from the etched facet 510 onto this cross-section plane d-d in FIG. 5b.

The layers either side of the active region 525, and extending either side of the trough containing the void 516, are now described. From top to bottom, the p-type InGaAs contact layer 520 is the top epitaxially-grown layer. Below that, a p-type InP cladding layer 122 is followed by an n-type InP blocking layer 523 and a p-type InP blocking layer 524, which are conventional for a buried heterostructure InP laser.

Below the blocking layers, the n-type InP spacer/contact layer 244, the quaternary etch stop layer 246, the n-type InP buffer layer 134 and substrate 136 are the same as under the active region 525, except the n-type InP spacer/contact layer 244 is thinner, having being partially consumed by the mesa etch in the conventional buried heterostructure process.

FIG. 6 illustrates a cantilevered suspended ridge laser in accordance with another embodiment of the present invention. The suspended beam 304 is supported at only one end 602, and is cantilevered over the void, so it is not supported at the other end 604.

FIG. 7 illustrates a suspended ridge laser in accordance with another embodiment of the present invention. The suspended beam 304 is supported at one end 702, and is supported over the void from underneath by a pillar 704. It may be supported by other pillars (not shown), which may be cylindrical or have other shapes.

FIG. 8 illustrates a suspended ridge laser in accordance with another embodiment of the present invention. The suspended beam 304 is supported at one end 802, and is supported over the void from underneath along its length by a fin 804. The fin is narrow, such that the etched void 806 extends under the suspended beam 304 from its sides far enough to reach under the active region through which the current in the circuit is directed vertically. For thermal isolation of the beam, the fin 804 has one or more holes in it (not shown), such that the etched void extends fully under the suspended beam's width, through the one or more holes located along the beam's length. The suspended beam 304 has both n-and p-contacts on it, so electrical current can be supplied to and from the active region in the beam without the current having to go via the fin between the active region and the substrate.

FIG. 9 illustrates a suspended ridge laser in accordance with another embodiment of the present invention. The suspended beam 304 is supported at one end 902, and is supported over the void from underneath by a wall 904. The wall 904 has preferentially-etched sloping sides, like the preferentially-etched sloped abutment 334 at the other end of the suspended beam. Unlike the flanges 350, 340 described with reference to FIG. 3c, the wall 904 is not at the end of the suspended beam 304. Thus, the end of the suspended beam 304 is cantilevered over the void and is not supported under the facet 906.

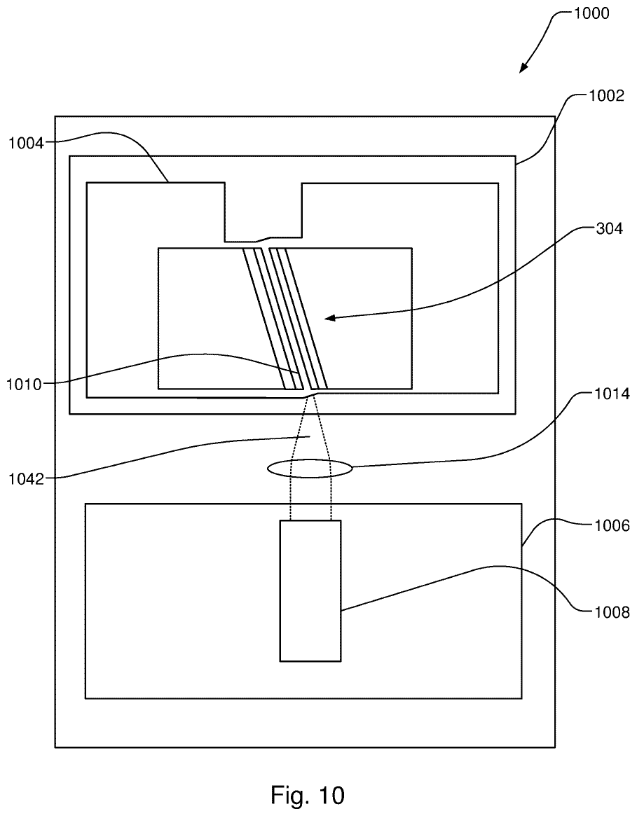

FIG. 10 illustrates, in schematic form, a photonic chip assembly in accordance with an embodiment of the present invention.

A photonic chip assembly 1000 has a photonic chip 1002 comprising one 1004 or more active photonic devices as described with reference to FIGS. 2a to 5c.

The assembly also has a photonic integrated circuit 1006 having a coupled waveguide 1008 aligned to be optically coupled to the waveguide 1010 of the suspended beam 304. In this example of a laser, the suspended active optical device outputs optical radiation 1042 through its optical coupling region. In this example a lens 1014 is provided to improve the optical coupling.

In the examples described with reference to FIGS. 6 to 10, the suspended beam 304 is a laser fabricated as shown in FIG. 3b, but other examples (not shown) may have different active photonic device structures, such as those 404, 504 illustrated in FIG. 4b and FIG. 5b, or devices that are not lasers.

1. An active photonic device comprising:
a substrate;
an epitaxial layer structure epitaxially grown on the substrate and comprising an active region to provide optical gain to radiation and comprising a doped layer to convey current to supply power to the active region;
a suspended beam that is elongate and supported over an etched void between the suspended beam and the substrate, the etched void extending fully under the suspended beam's width, the suspended beam comprising:
at least part of the active region;
a waveguide that is elongate and configured to guide the radiation along the suspended beam's length; and
at least part of the doped layer; and
one or more electrodes arranged with the at least part of the doped layer to direct current vertically through the at least part of the active region above the etched void.

2. The active photonic device of claim 1, wherein the one or more electrodes are arranged with the at least part of the doped layer to direct current lengthwise in the suspended beam.

3. The active photonic device of claim 1, wherein the suspended beam further comprises a grating at least partially periodic along the suspended beam's length.

4. The active photonic device of claim 1, wherein the suspended beam is supported at an end of the waveguide over the void.

5. The active photonic device of claim 1, further comprising a flange at an end of the waveguide, the flange supporting the suspended beam, wherein the flange comprises a facet.

6. The active photonic device of claim 5, wherein the flange comprises an etched facet.

7. The active photonic device of claim 1, wherein the suspended beam is supported over the void only at both ends of the waveguide.

8. The active photonic device of claim 1, wherein the suspended beam is cantilevered over the void.

9. The active photonic device of claim 1, wherein the suspended beam is supported over the void from underneath.

10. The active photonic device of claim 1, wherein the void comprises air.

11. The active photonic device of claim 1, wherein the suspended beam has an etch stop layer below the active region as its lower layer.

12. The active photonic device of claim 1, wherein the suspended beam has sidewalls and has a protective coating on its sidewalls.

13. The active photonic device of claim 1, wherein the suspended beam has sidewall and further comprising opposing sidewalls facing the suspended beam's sidewalls, wherein the opposing sidewalls have a protective coating.

14. The active photonic device of claim 1, comprising a trough that includes the void, the trough comprising a planar opposing sidewall facing a sidewall of the suspended beam's sidewall, wherein the planar opposing sidewall has its plane at a first angle with respect to a crystallographic plane of the substrate such that in use with a preferential wet void etch a first wet etch front is pinned to the base of the planar opposing sidewall.

15. The active photonic device of claim 14, wherein the suspended beam has a planar sidewall with its plane at a second angle, different from the first angle, with respect to the crystallographic plane of the substrate such that in use with the preferential wet void etch a second etch front of the preferential wet void etch is unpinned from the base of the suspended beam's sidewall, to allow more undercutting of a lower surface of the suspended beam compared to undercutting of the planar opposing sidewall by the preferential wet void etch.

16. The active photonic device of claim 1, further comprising a heater operable to heat the waveguide.

17. A photonic chip comprising the active photonic device of claim 1.

18. A photonic chip assembly comprising the photonic chip of claim 17 and a photonic integrated circuit having a coupled waveguide aligned to be optically coupled to the waveguide of the suspended beam.

19. A method of fabrication of a suspended active photonic device, the method comprising:
providing a layer structure epitaxially grown on a substrate and comprising an active region for providing optical gain to radiation and comprising a doped layer for conveying current supplying power to the active region;
fabricating in the epitaxial layer structure an elongate waveguide configured to guide the radiation;
fabricating an elongate suspended beam supported over an etched void between the suspended beam and the substrate, the etched void extending fully under the suspended beam's width, the suspended beam comprising at least part of the active region, at least part of the doped layer and the elongate waveguide, with the elongate waveguide configured to guide the radiation along the suspended beam's length; and
before etching the void, fabricating one or more electrodes arranged with the at least part of doped layer to direct current vertically through the at least part of active region above the etched void.

20. The method of claim 19, further comprising fabricating the one or more electrodes arranged with the at least part of doped layer to direct current in lengthwise in the suspended beam.
